(19) United States
(12) Patent Application Publication
(10) Pub. No.: US 2012/0094405 A1
(43) Pub. Date: Apr. 19, 2012

(54) METHOD FOR MANUFACTURING LED PACKAGE

(75) Inventors: HSIN-TUNG CHIANG, Hukou (TW); KO-WEI CHIEN, Hukou (TW)

(73) Assignee: ADVANCED OPTOELECTRONIC TECHNOLOGY, INC., Hsinchu Hsien (TW)

(21) Appl. No.: 13/220,708

(22) Filed: Aug. 30, 2011

(30) Foreign Application Priority Data
Oct. 19, 2010 (CN) 201010513337.4

(51) Int. Cl. H01L 33/50

(52) U.S. Cl. 438/27; 257/E33.061

(57) ABSTRACT

A method for manufacturing an LED package includes following steps: providing a substrate, wherein the substrate includes a plurality of package carriers and each package carrier includes two lead frames. Each package carrier includes a first surface and a recession surrounded by a bottom wall and a sidewall is defined on the first surface. Mount an LED chip on the bottom wall and electrical connecting the LED chip and the two lead frames, form an encapsulation in the recession; form a hydrophobic layer on the package carrier and the encapsulation; cut the substrate into a plurality of LED package structure.

### BACKGROUND

1. Technical Field

The disclosure relates to light emitting diodes, and particularly to a method for manufacturing an LED package.

2. Description of the Related Art

Light emitting diodes (LEDs) have many advantages, such as high luminosity, low operational voltage, low power consumption, compatibility with integrated circuits, easy driving, long term reliability, and environmental friendliness. Such advantages have promoted the wide use of the LEDs as a light source. Now, light emitting diodes are commonly applied in environmental lighting.

During a process of the cutting of a common LED package, the cooling liquid passes through a gap of an encapsulation of the common LED package. Thus, the cooling liquid will cause damage to the LED.

Therefore, it is desirable to provide a method for manufacturing an LED package which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present method for manufacturing an LED package. Moreover, in the drawings, like reference numerals designate corresponding parts throughout the views.

FIG. 1 is a processing flow of manufacturing an LED package.

FIG. 2 is a schematic view of manufacturing the LED package of FIG. 1.

### DETAILED DESCRIPTION

Embodiments of a method for manufacturing an LED package as disclosed are described in detail here with reference to the drawings.

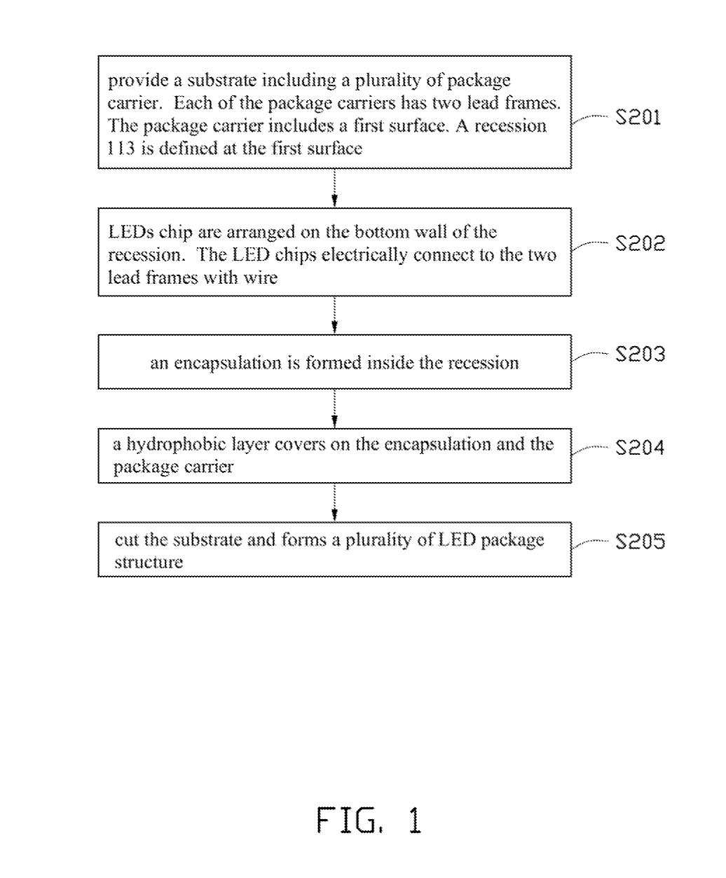

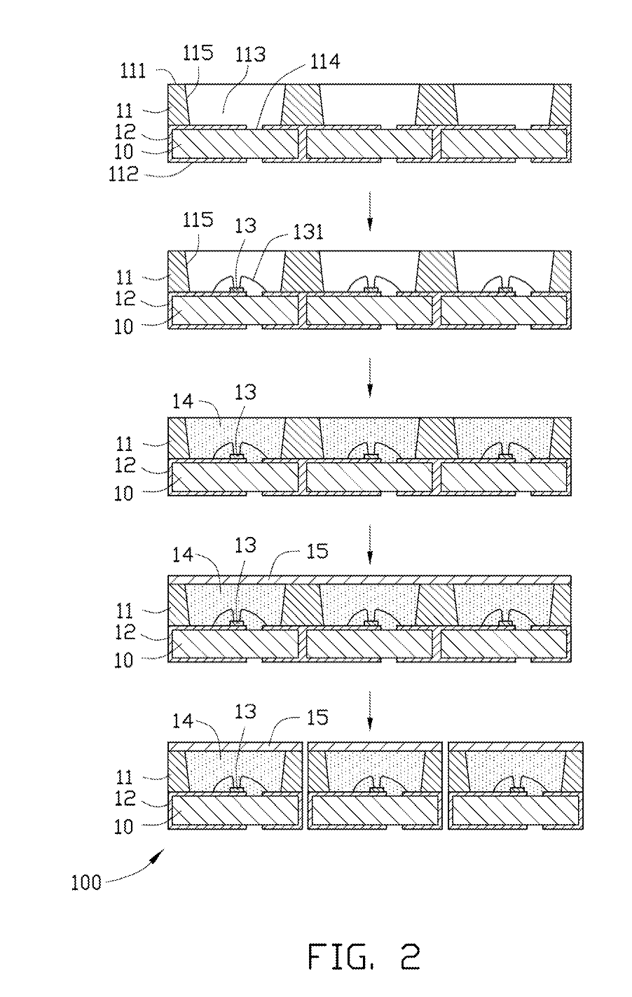

Referring to FIG. 1-2, a substrate 10 is provided in step S201. The substrate 10 includes a plurality of package carriers 11. Each of the package carriers 11 has two lead frames 12. Each package carrier 11 includes a first surface 111 and a second surface 112 opposite to the first surface 111. A recession 113 is arranged on the first surface 111. The recession 113 is defined by a bottom wall 114 and a side wall 115. The bottom wall 114 and the side wall 115 are formed by different materials and fixed together with glue. Alternatively, the bottom wall 114 and the sidewall 115 can be formed in one piece. The package carrier 11 can be high thermal conductivity and electrically insulated material. Materials having high thermal conductivity and electrically insulated material can be graphite, silicon, ceramics, diamond, epoxy, or epoxy silane.

One end of each of the lead frames 12 is exposed on the bottom wall 114 of the recession 113. The other end of the lead frames 12 is arranged on the second surface 112 of the package carrier 11. The lead frames 12 can be metal or metal alloy.

In step S202, LED chips 13 are arranged on the lead frames 12 in the recessions 113 with glue. Alternatively, the LED chips 13 can be arranged on the bottom walls 114. The LED chips 13 electrically connect to the two lead frames 12 with metal wires 131. The LED chips 13 also electrically connect to the two lead frames 12 by flip chip or eutectic method, in accordance with alternative embodiments. Light emitting direction of the LED chip 13 is controlled by the side wall 115 reflecting the light from the LED chip 13.

In step S203, an encapsulation 14 is formed inside each of the recessions 113. The encapsulation 14 covers the LED chips 13 and the bottom walls 114. The encapsulation 14 is used for preventing the vapor and dust from affecting the LED chips 13. The encapsulation 14 can be silicone, epoxy, or other combinations. The encapsulation 14 further includes fluorescent conversion materials. The fluorescent conversion materials can be garnet base phosphors, silicate base phosphors, sulfide base phosphors, thio gallium salt phosphors, or nitride based phosphors.

In step S204, a hydrophobic layer 15 covers the encapsulation 14 and the package carrier 11. The hydrophobic layer 15 can be opaque material and must be removed by a polishing or etching method after a cutting process. The hydrophobic layer 15 also can be transparent material and does not need to be removed after the cutting process.

In step S205, the substrate 10 is cut thereby forming a plurality of LED package structures 100. The substrate 10 is cut with tools. During the cutting process, the hydrophobic layer 15 resists a cooling liquid. Thus, the cooling liquid does not enter an interior of package structure 100 via a gap between the encapsulation 14 and the side wall 115 of the package carrier 11 due to the hydrophobic layer 15. The hydrophobic layer 15 protects internal devices of the LED package structure 100.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for manufacturing an LED package, including steps:
providing a substrate including a plurality of package carriers, each of the package carriers having two lead frames, a top surface, a recession surrounded by a bottom wall, and a side wall defined at the top surface;
arranging an LED chip on a bottom of the recession and connecting to the two lead frames;
forming an encapsulation inside the recession;
covering a hydrophobic layer on the package carrier and the encapsulation;
cutting the substrate and forming a plurality of LED package structure.

2. The method for manufacturing the LED package of claim 1, wherein the hydrophobic layer is opaque material and is removed after a cutting process.

3. The method for manufacturing the LED package of claim 1, wherein the hydrophobic layer is removed by a polishing or etching method.

4. The method for manufacturing the LED package of claim 1, wherein the hydrophobic layer is transparent material and is maintained after the cutting process.

5. The method for manufacturing the LED package of claim 1, wherein the substrate is cut by tools.

6. The method for manufacturing the LED package of claim 1, wherein one end of each of the lead frames is exposed on the bottom wall of the recession, and the other end of the lead frames is arranged on a second surface of the package carrier.

7. The method for manufacturing the LED package of claim 6, wherein the LED chips are arranged on the lead frames of the recession.

8. The method for manufacturing the LED package of claim 1, wherein the LED chip electrically connects to the two lead frames by flip chip or eutectic method.

9. The method for manufacturing the LED package of claim 1, wherein the LED chip electrically connects to the two lead frames with metal wires.

10. The method for manufacturing the LED package of claim 1, wherein the encapsulation is made of be silicone, or epoxy.

11. The method for manufacturing the LED package of claim 1, wherein the encapsulation further includes fluorescent conversion materials, and the fluorescent conversion materials are garnet base phosphors, silicate base phosphors, sulfide base phosphors, thio gallium salt phosphors, or nitride based phosphors.
